(19) United States
(12) Patent Application Publication
(10) Pub. No.: US 2013/0279973 A1
(43) Pub. Date: Oct. 24, 2013

(54) CIRCUIT BOARD MOUNTING ASSEMBLY

(71) Applicants: Hong Fu Jin Precision Industry (ShenZhen) Co., Ltd., (US); HON HAI PRECISION INDUSTRY CO., LTD., New Taipei (TW)

(72) Inventor: ZHAN-YANG LI, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/726,151

(22) Filed: Dec. 23, 2012

(30) Foreign Application Priority Data
Apr. 20, 2012 (CN) 201210117633.1

(51) Int. Cl. H05K 7/02

(52) U.S. Cl. CPC H05K 7/02
USPC 403/327; 403/361

(57) ABSTRACT

A circuit board mounting assembly includes a base panel, a circuit board, and a mounting apparatus. The base panel includes a hollow post. A groove is defined in the hollow post. The mounting apparatus includes a securing member and a driving member. The securing member includes a pair of engaging balls. The driving member includes a first engaging rod and a second engaging rod that are movable along its axial direction. A diameter of the first engaging rod is greater than the diameter of the second engaging rod. When the second engaging rod is located between and resisted against the pair of engaging balls, the pair of engaging balls is not engaged with the groove. When the first engaging rod is located between and resisted against the pair of engaging balls, and the pair of engaging balls is engaged with the groove for locking the circuit board to the panel.

### BACKGROUND

1. Technical Field

The present disclosure relates to a circuit board mounting assembly.

2. Description of Related Art

An electronic device, such as a computer, includes a chassis and a circuit board attached on a panel of the chassis. A mounting post is attached on the panel. A first mounting hole is defined in the mounting post. A second mounting hole is defined in the circuit board and aligned with the first mounting hole. A fastener extends through the second mounting hole and the first mounting hole to secure the circuit board to the panel. However, the fastener is inconvenient to detach from the first mounting hole, and the circuit board is not easy to be detached from the panel.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of a circuit board mounting assembly in accordance with an embodiment.

FIG. 2 is another view of a header member of the circuit board mounting assembly of FIG. 1.

FIG. 3 is an assembled view of the circuit board mounting assembly of FIG. 1.

FIG. 4 is a cross-sectional view taken along line IV-IV of FIG. 3, showing the circuit board mounting assembly in an unlocked state.

FIG. 5 is similar to FIG. 4, but showing the circuit board mounting assembly in a locked state.

### DETAILED DESCRIPTION

The disclosure is illustrated by way of example and not by way of limitation. In the figures of the accompanying drawings, like references indicate similar elements. It should be noted that references to “an” or “one” embodiment in this disclosure are not necessarily to the same embodiment, and such references mean “at least one.”

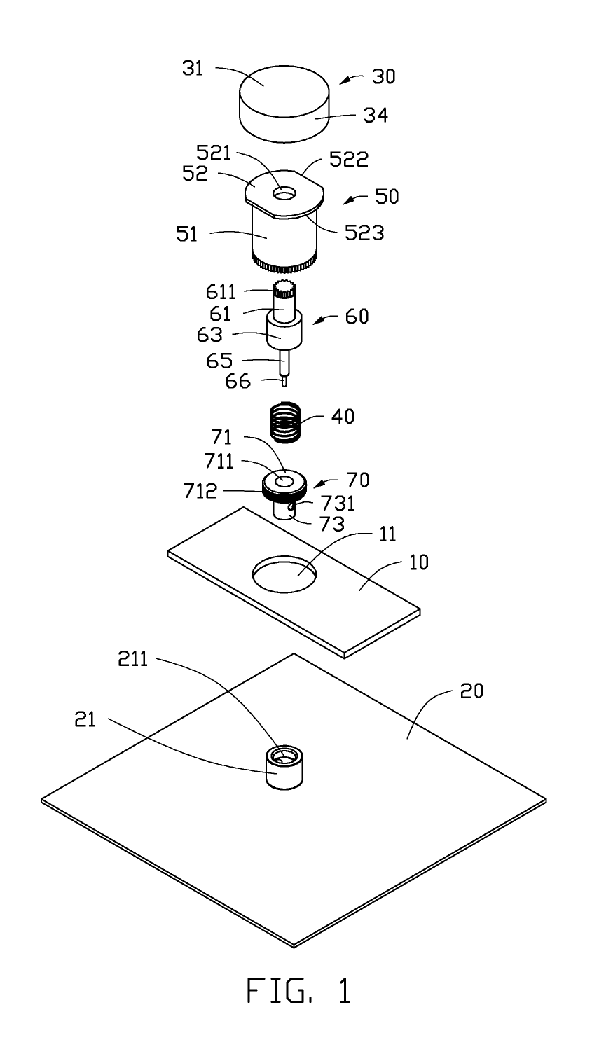

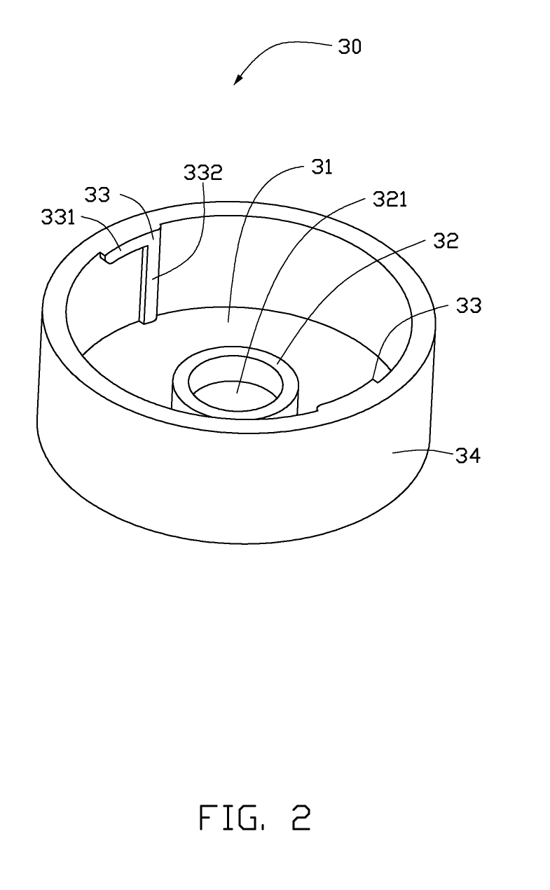

FIGS. 1 and 2 show an embodiment of a circuit board mounting assembly. The circuit board mounting assembly includes a circuit board 10, a base panel 20, and a mounting apparatus used for securing the circuit board 10 to the base panel 20. The mounting apparatus includes a header member 30, a spring 40, a mounting member 50, a driving member 60, and a securing member 70. In one embodiment, the base panel 20 is a part of an electronic device enclosure.

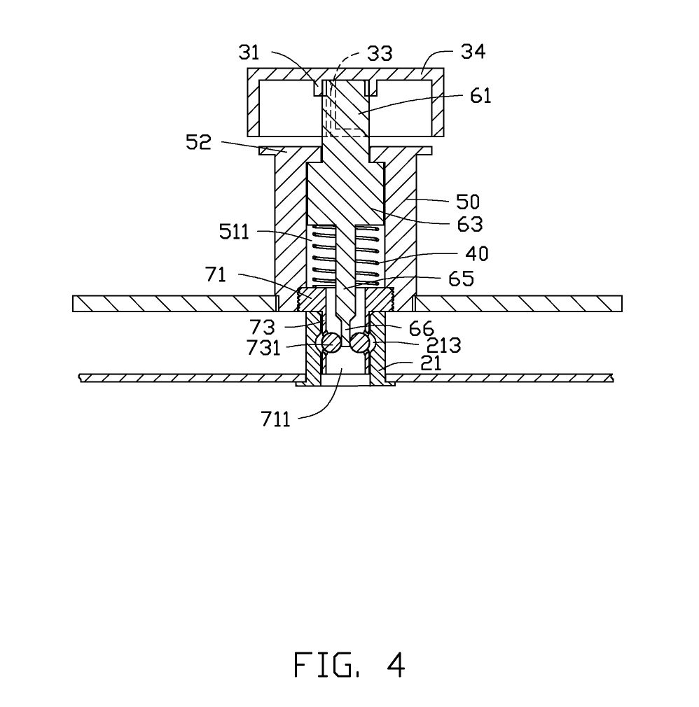

A first mounting hole 11 is defined in the circuit board 10. A mounting post 21 is attached to the base panel 20 and protrudes from the base panel 20. A second mounting hole 211 is defined in the mounting post 21. An arc-shaped groove 213 (see FIG. 4) is defined in an interior surface of the mounting post 21 and forms a circle around the second mounting hole 211.

The header member 30 has a hollow cylindrical shape and includes a round panel 31 and a ring-shaped body 34 extending from the round panel 31. The round panel 31 is located at a top of the header member 30. A ring-shaped post 32 extends from a central portion of the round panel 31. A hole 321 is defined in the ring-shaped post 32. A pair of latch protrusions 33 protrudes from an inner surface of the ring-shaped body 34. The pair of latch protrusions 33 is symmetrical to each other about an axis of the header member 30. Each of the pair of latch protrusions 33 has an L shape and includes a vertical portion 332 and a horizontal portion 331 connecting with the vertical portion 332. The vertical portion 332 is substantially parallel to the axis of the header member 30. The horizontal portion 331 is connected to a lower flange of the ring-shaped body 34 and has an arc-shaped. A lower surface of the horizontal portion 331 lies in the same plane as the lower flange of the ring-shaped body 34.

The mounting member 50 includes a cylindrical body 51 and a head 52 connected with a top of the cylindrical body 51. The cylindrical body 51 is hollow and has an accommodating space 511 (see FIG. 4) for mounting the driving member 60. A through hole 521 is defined in a central portion of the head 52 and communicates with the accommodating space 511. The head 52 protrudes from the cylindrical body 51 and includes a pair of arc-shaped portions 523 and a pair of flat portions 522 located between the pair of arc-shaped portions 523. The head 52 is shaped like a circle with a pair of symmetrical cutouts. An inner diameter of the cylindrical body 51 is greater than the diameter of the through hole 521. An outer diameter of the cylindrical body 51 is substantially equal to the diameter of the first mounting hole 11. A plurality of saw tooth-shaped grooves is defined in a lower end of the cylindrical body 51.

The driving member 60 includes a mounting rod 61, a sliding post 63 connecting with a bottom of the mounting rod 61, a first engaging rod 65 connected to a bottom of the sliding post 63, and a second engaging rod 66 connecting with a bottom of the first engaging rod 65. An engaging end 611 is located at an upper end of the mounting rod 61. A plurality of saw tooth-shaped groove is defined in the engaging end 611. Each of the mounting rod 61, the sliding post 63, the first engaging rod 65, and the second engaging rod 66 has a cylindrical shape. A diameter of the sliding post 63 is greater than the diameter of the mounting rod 61. A diameter of the first engaging rod 65 is less than the diameter of the mounting rod 61, but greater than the diameter of the second engaging rod 66. A diameter of the mounting rod 61 is slightly greater than the diameter of the hole 321 and can be fixed in the hole 321. A diameter of the sliding post 63 is substantially equal to the inner diameter of the cylindrical body 51. The sliding post 63 is slidable in the accommodating space 511 along an axis of the mounting member 50. A diameter of the second mounting hole 211 is greater than the diameter of the first engaging rod 65.

The securing member 70 includes a cap 71 and a tubular post 73 extending downwardly from a lower side of the cap 71. A diameter of the cap 71 is greater than the diameter of the tubular post 73. A third mounting hole 711 is defined in a central portion of the cap 71. An outer diameter of the tubular post 73 is slightly greater than the diameter of the second mounting hole 211. The tubular post 73 can be fixed in the second mounting hole 211. A plurality of saw tooth-shaped grooves 712 is defined in a side surface of the cap 71. A pair of engaging balls 731 is attached to the tubular post 73. The tubular post 73 has deformability. When the tubular post 73 is at a natural state, the pair of engaging balls 731 do not protrude from the tubular post 73. When the tubular post 73 is at a deformed, expanded, state, the pair of engaging balls 731 move away from each other and protrude from the tubular post 73.

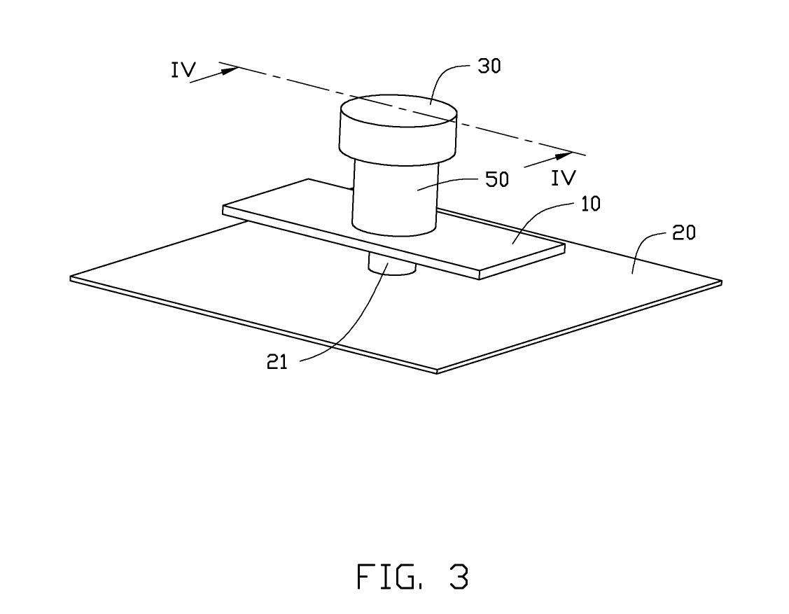

FIGS. 3 to 5 show that in assembly, the mounting rod 61 extends through the through hole 521. The engaging end 611 is fixed in the hole 321. The header member 30 is attached to the engaging end 611 and located above the mounting member 50. The sliding post 63 is received in the accommodating space 511. The spring 40 is attached to the first engaging rod 65. The second engaging rod 66 and a lower part of the first engaging rod 65 extend through the third mounting hole 711. The cap 71 is secured in a lower portion of the cylindrical body 51. An upper end of the spring 40 abuts against the sliding post 63. A lower end of the spring 40 abuts against the cap 71. Thus, the mounting apparatus is assembled. The lower portion of the cylindrical body 51 is fixed in the first mounting hole 11. Lower surfaces of the cylindrical body 51, the cap 71, and the circuit board 10 lie in the same plane. The tubular post 73 protrudes at a lower side of the circuit board 10 and engages in the second mounting hole 211. The pair of engaging balls 731 is aligned with the arc-shaped groove 213.

When the circuit board 10 is in an unlocked state (see FIG. 4), the header member 30 is spaced from the head 52. The spring 40 is in a first deformed state. A lower end of the second engaging rod 66 is located between the pair of engaging balls 731. The tubular post 73 is at a natural state. A distance between the pair of engaging balls 731 is substantially equal to the diameter of the second engaging rod 66. The pair of engaging balls 731 is disengaged from the arc-shaped groove 213. The tubular post 73 can be disengaged away from the mounting post 21, thereby detaching the circuit board 10 from the base panel 20.

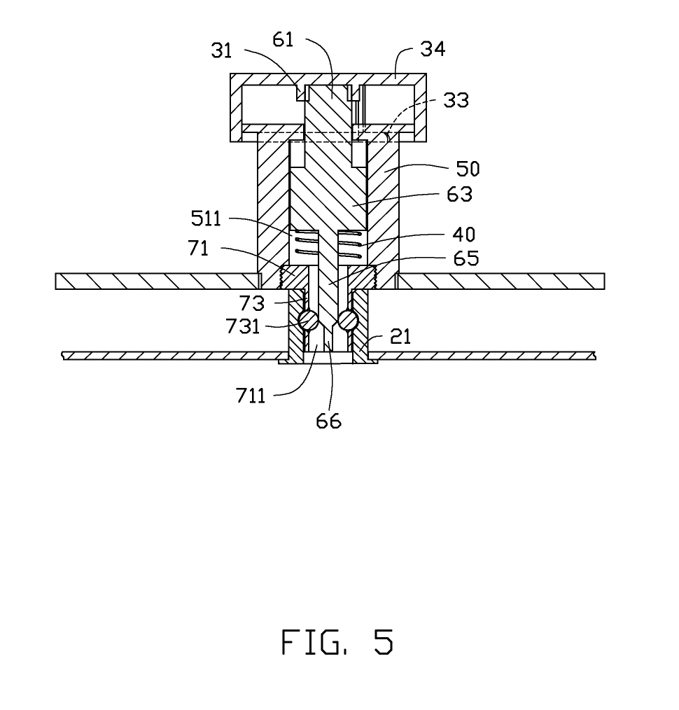

To lock the circuit board 10 (See FIG. 5), the header member 30 is rotated together with the driving member 60 to cause the pair of latch protrusions 33 to align with the pair of flat portions 522. The header member 30 is pressed down. The pair of latch protrusions 33 passes through the pair of flat portions 522. The header member 30 moves downwards until the second engaging rod 66 abutting against the base panel 20. The header member 30 is rotated along a first direction. The pair of arc-shaped portions 523 is biased against an upper flange of the horizontal portion 331 and hooked by the horizontal portion 331, thereby securing the header member 30 to the mounting member 50. The vertical portion 332 abuts against the head 52, thereby preventing excess rotation of the header member 30 along the first direction. The driving member 60 is pressed down by the header member 30. The sliding post 63 slides in the accommodating space 511 downwardly. The spring 40 is compressed to a second deformed state. The first engaging rod 65 abuts against the pair of engaging balls 731. The pair of engaging balls 731 is engaged in the arc-shaped groove 213 preventing the circuit board 10 from disengaging from the base panel 20. Thus, the circuit board 10 is locked to the base panel 20.

To detach the circuit board 10 from the base panel 20, the header member 30 is rotated along a second direction that is opposite to the first direction. The pair of latch portions 33 is disengaged from the pair of arc-shaped portions 523 and aligned with the pair of flat portions 522. The spring 40 returns to the first deformed state and pushes the driving member 60 upwards. The first engaging rod 65 disengages from the pair of engaging balls 731. The pair of engaging balls 731 moves towards each other until the tubular post 73 resumes its original state. The mounting apparatus returns to the unlocked state as shown in FIG. 4. The circuit board 10 can be detached from the base panel 20.

While the present disclosure has been illustrated by the description in this embodiment, and while the embodiment has been described in considerable detail, it is not intended to restrict or in any way limit the scope of the appended claims to such details. Additional advantages and modifications within the spirit and scope of the present disclosure will readily appear to those skilled in the art. Therefore, the present disclosure is not limited to the specific details and illustrative examples shown and described.

What is claimed is:

1. A circuit board mounting assembly comprising:
a base panel comprising a hollow post, a groove is defined in the hollow post;
a circuit board with a first mounting hole; and
a mounting apparatus, configured to lock the circuit board to the base panel, comprising: a securing member, extending in the hollow post via the first mounting hole, comprising a pair of engaging balls engageable with the groove; and a driving member comprising a first engaging rod and a second engaging rod that are movable in the securing member along its axial direction, and a diameter of the first engaging rod is greater than the diameter of the second engaging rod;
wherein when the circuit board is in an unlocked state, the second engaging rod is located between and resisted against the pair of engaging balls, and the pair of engaging balls is not engaged with the groove; when the circuit board is in a locked state, the first engaging rod is located between and resisted against the pair of engaging balls, and the pair of engaging balls is engaged with the groove for preventing the circuit board disengaging from the base panel.

2. The circuit board mounting assembly of claim 1, wherein the groove is arc-shaped and extends along a circumferential circle around an inner surface of the hollow post.

3. The circuit board mounting assembly of claim 1, wherein the mounting apparatus further comprises a header member attached to a top end of the driving member, and the header member is rotatable together with the driving member and capable of pushing the driving member to move along a first axial direction towards the base panel.

4. The circuit board mounting assembly of claim 3, wherein the mounting apparatus further comprises a spring located between the driving member and the securing member, and the spring is capable of pushing the driving member to move along a second axial direction that is opposite to the first axial direction.

5. The circuit board mounting assembly of claim 4, wherein the mounting apparatus further comprises a hollow mounting member, the top end of the driving member extends through the hollow mounting member and protrudes out from a top of the hollow mounting member, and the first engaging rod and the second engaging rod protrude out from a bottom of the hollow mounting member.

6. The circuit board mounting assembly of claim 5, wherein the hollow mounting member comprises a cylindrical body and an engaging head connected with a top of the cylindrical body, and the engaging head is engageable with the header member for retaining the circuit board at the locked state.

7. The circuit board mounting assembly of claim 6, wherein the header member has a hollow cylindrical shape and comprises a top panel and a ring-shaped body extending downwardly from the top panel, and a pair of latch protrusions protrudes from an inner surface of the ring-shaped body for engaging with the engaging head.

8. The circuit board mounting assembly of claim 7, wherein each of the pair of latch protrusions has an L shape and includes a vertical portion and a horizontal portion connected to the vertical portion, and the horizontal portion is connected to an arc flange of the ring-shaped body and engageable with the engaging head.

9. The circuit board mounting assembly of claim 8, wherein the engaging head is shaped like a circle with a pair of symmetrical cutouts and comprises a pair of arc-shaped portions and a pair of flat portions located between the pair of arc-shaped portions, the header member is movable towards or away from the engaging head when the pair of latch protrusions is aligned with the pair of flat portions, and the header member is rotatable from the pair of flat portions to the pair of arc-shaped portions to be hooked by the horizontal portion.

10. The circuit board mounting assembly of claim 9, wherein the securing member comprises a cap and a tubular post extending downwardly from the cap, the tubular post is deformable and the pair of engaging balls is attached to the tubular post and movable between a first position, where the tubular post is in an natural state, and the pair of engaging balls is disengaged from the groove, and a second position, where the tubular post is in a deformed, expanded state, and the pair of engaging balls is moved away from each other and engaged with the groove.

11. An assembly comprising:
a base panel comprising a hollow post, a groove is defined in the hollow post;
a circuit board with a first mounting hole;
a securing member, extending in the hollow post via the first mounting hole, comprising a pair of resilient legs and a pair of engaging balls attached to the pair of resilient legs; and
a driving member comprising a first engaging rod and a second engaging rod that are movable in the securing member along its axial direction, and a diameter of the first engaging rod is greater than the diameter of the second engaging rod;
wherein the driving member is movable between an unlocked position, where the second engaging rod is located between and resisted against the pair of engaging balls, and the pair of engaging balls is not engaged with the groove, and a locked position, where the first engaging rod is located between and resisted against the pair of engaging balls, and the pair of engaging balls is engaged with the groove for preventing the circuit board disengaging from the base panel.

12. The assembly of claim 11, wherein the groove is arc-shaped and extends along a circumferential circle around an inner surface of the hollow post.

13. The assembly of claim 11, further comprising a header member attached to a top end of the driving member, wherein the header member is rotatable together with the driving member and capable of pushing the driving member to move along a first axial direction towards the base panel.

14. The assembly of claim 13, further comprises a spring located between the driving member and the securing member, wherein the spring is capable of pushing the driving member to move along a second axial direction that is opposite to the first axial direction.

15. The assembly of claim 14, further comprising a hollow mounting member, wherein the top end of the driving member extends through the hollow mounting member and protrudes out from a top of the hollow mounting member, and the first engaging rod and the second engaging rod protrude out from a bottom of the hollow mounting member.

16. The assembly of claim 15, wherein the hollow mounting member comprises a cylindrical body and an engaging head connected with a top of the cylindrical body, and the engaging head is engageable with the header member for retaining the circuit board at the locked position.

17. The assembly of claim 16, wherein the header member has a hollow cylindrical shape and comprises a top panel and a ring-shaped body extending downwardly from the top panel, and a pair of latch protrusions protrudes from an inner surface of the ring-shaped body for engaging with the engaging head.

18. The assembly of claim 17, wherein each of the pair of latch protrusions has an L shape and includes a vertical portion and a horizontal portion connected to the vertical portion, and the horizontal portion is connected to an arc flange of the ring-shaped body and engageable with the engaging head.

19. The assembly of claim 18, wherein the engaging head is shaped like a circle with a pair of symmetrical cutouts and comprises a pair of arc-shaped portions and a pair of flat portions located between the pair of arc-shaped portions, the header member is movable towards or away from the engaging head when the pair of latch protrusions is aligned with the pair of flat portions, and the header member is rotatable from the pair of flat portions to the pair of arc-shaped portions to be hooked by the horizontal portion.

20. The assembly of claim 19, wherein the securing member further comprises a cap connected to tops of the pair of resilient legs, the cap is secured in a lower portion of the hollow mounting member, and the lower portion is secured in the first mounting hole.
